(19) United States
(12) Patent Application Publication
(10) Pub. No.: US 2023/0129291 A1
(43) Pub. Date: Apr. 27, 2023

(54) BEVEL ETCHER USING ATMOSPHERIC PLASMA

(71) Applicant: ASM IP Holding B.V., Almere (NL)

(72) Inventors: Yoshio Susa, Tokyo (JP); Yoshiyuki Kikuchi, Tokyo (JP)

(21) Appl. No.: 17/970,987

(22) Filed: Oct. 21, 2022

Related U.S. Application Data
(60) Provisional application No. 63/271,880, filed on Oct. 26, 2021.

(51) Int. Cl. H01L 21/3065; H01L 21/67

(52) U.S. Cl. CPC H01L 21/3065; H01L 21/67063; H01L 21/67207

(57) ABSTRACT

A method for etching a bevel edge of a substrate. The method includes providing a substrate with a bevel edge after a thin film has been deposited on a top surface of the substrate and rotating the substrate about its center axis. The method also includes, during the rotating, etching the bevel edge by directing flow of atmospheric plasma onto the bevel edge. The flow is parallel to the top surface of the substrate, such as orthogonal to a plane containing a region of the bevel edge being etched by the atmospheric plasma, which may be O₂ atmospheric plasma. The etching is performed without loss of thickness of the thin film on the top surface at a radius spaced apart from an outer radius of the substrate. The substrate may be a silicon (Si) wafer, and the thin film may be a carbon film, amorphous carbon, SiC, SiO, or SiN.

### CROSS-REFERENCE TO RELATED APPLICATIONS

This application claims priority to U.S. Provisional Patent Application Ser. No. 63/271,880 filed Oct. 26, 2021 titled BEVEL ETCHER USING ATMOSPHERIC PLASMA, the disclosure of which is hereby incorporated by reference in its entirety.

### FIELD OF THE DISCLOSURE

The present disclosure relates generally semiconductor manufacturing and corresponding systems for performing the manufacturing, and, more particularly, to a bevel etcher for use in a plasma deposition apparatus or system, such as one adapted for plasma chemical vapor deposition (CVD) and/or plasma atomic layer deposition (ALD), operable to form a film on a substrate (e.g., a wafer).

### BACKGROUND

In the semiconductor industry, integrated circuits are formed from a substrate or a wafer over which are formed patterned microelectronic layers. In the processing of the substrate in a deposition apparatus or system, plasma is often employed to deposit materials or films on the substrate and to etch portions of the films deposited on the substrate. For example, plasma or plasma-enhanced CVD (which may be labeled plasma CVD or PECVD) is widely used to fabricate semiconductor structures. In general, “chemical vapor deposition” (CVD) may refer to any process in which a substrate (e.g., a wafer) is exposed to one or more volatile precursors, which react and/or decompose on a substrate surface to produce a desired deposition.

Plasma or plasma enhanced CVD (or PECVD) is common throughout the semiconductor industry. In the same deposition systems (e.g., multi-chamber deposition assemblies or tools), plasma or plasma enhanced atomic layer deposition (ALD) (or PEALD) may be utilized that uses chemical precursors as with thermal ALD while cycling an RF-plasma to create desirable chemical reactions in a highly controlled manner in a reaction chamber or vacuum chamber to create desired material thin films on substrates.

There can be a number of deposition system design challenges with the use of plasma ALD or CVD. For example, it is well known in the semiconductor industry that film delamination can occur at the edge or side of a wafer, which may be considered the wafer bevel or a bevel edge of a substrate or wafer. This can be a particular issue after plasma ALD or CVD of a carbon layer or film. Delamination continues to be a problem for many semiconductor equipment companies as film delamination can prevent a wafer from going to a lithography process or other next step of manufacturing.

A number of ideas have been suggested for addressing the delamination problem, but none have been wholly successful or adopted by the semiconductor manufacturing industry. As one example, a device or “bevel etcher” has been proposed for cleaning a bevel edge of a semiconductor substrate. This device design includes a lower electrode assembly that has a top surface and is adapted to support the substrate. An upper electrode assembly is also provided that has a bottom surface opposing the top surface, e.g., the substrate is sandwiched between the two electrode assemblies. The lower and upper electrode assemblies generate plasma for cleaning the bevel edge of the substrate, which is disposed between the top and bottom surfaces of the two electrode assemblies during operation of this bevel etcher. The device also includes a mechanism for suspending the upper electrode assembly over the lower electrode assembly supporting the substrate and for adjusting its tilt angle and horizontal location relative to the lower electrode assembly. In use, this bevel etcher is typically provided in a vacuum chamber (differing from the one used to perform the carbon deposition), and the confined plasma generated by operation of the two electrode assemblies functions to remove, for example, a carbon film at the edge of a substrate or wafer.

Any discussion of problems and solutions set forth in this section has been included in this disclosure solely for the purpose of providing a context for the present disclosure and should not be taken as an admission that any or all of the discussion was known at the time the invention was made.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

According to one aspect of the description, a method is provided for etching a bevel edge of a substrate. The method includes providing a substrate with a bevel edge after a thin film has been deposited on a top surface of the substrate and then rotating the substrate about a center axis. The method also includes, during the rotating, etching the bevel edge by directing a flow of atmospheric plasma onto the bevel edge.

In some implementations of the method, the flow is parallel to the top surface of the substrate, such as orthogonal to a plane containing a region of the bevel edge being etched by the atmospheric plasma. In these and other cases, the atmospheric plasma may be an O₂ atmospheric plasma, an Ar/O₂ atmospheric plasma, or a N₂/O₂ atmospheric plasma, and the rotating includes rotating the substrate at a rotation rate in the range of 20 to 500 RPM. In some useful implementations, the etching is performed without loss of thickness of the thin film on the top surface at a radius spaced apart from an outer radius of the substrate less 5 mm. The substrate may be a silicon (Si) wafer, and the thin film comprises at least one of a carbon film, amorphous carbon, SiC, SiO, and SiN.

In the method, the providing step may include positioning the substrate upon a rotation mechanism operable to perform the rotating step, and the rotation mechanism may be or include a notch aligner, a wafer cooling stage, or a rotating stage. It may be desirable that the rotation mechanism is located in a space of a plasma deposition system that is maintained at atmospheric pressure during operations of the plasma deposition system.

According to other aspects of the description, a bevel etcher apparatus is described that includes a chamber and a rotation mechanism adapted for supporting and rotating a wafer about a center axis. The apparatus also includes an atmospheric plasma unit with a nozzle outputting an atmospheric plasma, and the nozzle is oriented in the chamber to provide a crossflow of the atmospheric plasma to an outer edge of the wafer during the rotating by the rotation mechanism. The chamber may be maintained at atmospheric pressure during operation of the rotation mechanism and the atmospheric plasma unit. The nozzle can be configured to provide the atmospheric plasma as a planar sheet or a sharp head, and the crossflow is oriented such that the planar sheet is orthogonal to a plane containing a point of the outer edge of the wafer proximate to the atmospheric plasma unit.

In some embodiments of the apparatus, the rotation mechanism is configured to support the wafer with a top surface in a horizontal plane, and the planar sheet or sharp head of the atmospheric plasma is provided in a vertical plane. In these or other cases, the atmospheric plasma is or includes O₂ atmospheric plasma, Ar/O₂ atmospheric plasma, or N₂/O₂ atmospheric plasma. Further, the apparatus may be implemented with the rotation mechanism is or includes a notch aligner, a wafer cooling stage, or a rotating stage, and the rotation mechanism can be operable to rotate the wafer at a rotation rate in the range of 10 to 500 RPM.

For the purpose of summarizing the disclosure and the advantages achieved over the prior art, certain objects and advantages of the disclosure have been described herein above. Of course, it is to be understood that not necessarily all such objects or advantages may be achieved in accordance with any particular embodiment of the disclosure. Thus, for example, those skilled in the art will recognize that the embodiments disclosed herein may be carried out in a manner that achieves or optimizes one advantage or group of advantages as taught or suggested herein without necessarily achieving other objects or advantages as may be taught or suggested herein.

All of these embodiments are intended to be within the scope of the disclosure. These and other embodiments will become readily apparent to those skilled in the art from the following detailed description of certain embodiments having reference to the attached figures, the disclosure not being limited to any particular embodiment(s) discussed.

### BRIEF DESCRIPTION OF THE DRAWING FIGURES

While the specification concludes with claims particularly pointing out and distinctly claiming what are regarded as embodiments of the disclosure, the advantages of embodiments of the disclosure may be more readily ascertained from the description of certain examples of the embodiments of the disclosure when read in conjunction with the accompanying drawings. Elements with the like element numbering throughout the figures are intended to be the same.

FIGS. 1A and 1B are top and side functional schematic views of a chamber or module in which a bevel etcher assembly of the present description is positioned and operated to clean or etch a substrate or wafer edge.

FIGS. 2A and 2B provide a top view of a whole system described herein and a side view of a bevel etcher assembly, respectively, of the present description.

FIG. 3 illustrates bevel etching test results achieved with the bevel etcher design of the present description.

FIGS. 4A and 4B are graphs illustrating measurement points on an etched or cleaned wafer and a profile of etching amount on the wafer edge after bevel etching with a bevel etcher of the present description.

FIG. 5 is a process flow diagram for a deposition process that includes an edge etching according to the present description using atmospheric plasma.

### DETAILED DESCRIPTION

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure should not be limited by the particular embodiments described herein.

The illustrations presented herein are not meant to be actual views of any particular material, apparatus, structure, or device, but are merely representations that are used to describe embodiments of the disclosure.

As used herein, the term “substrate” and “wafer” may be used interchangeably and may refer to any underlying material or materials that may be used, or upon which, a device, a circuit, or a film may be formed.

As used herein, the term “chemical vapor deposition” (CVD) may refer to any process wherein a substrate is exposed to one or more volatile precursors, which react and/or decompose on a substrate surface to produce a desired deposition.

As used herein, the term “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

As described in greater detail below, various details and embodiments of the disclosure may be utilized in conjunction with a reaction chamber configured for a multitude of deposition processes, including but not limited to plasma-enhanced chemical vapor deposition (PECVD or plasma CVD) and/or to plasma-enhanced atomic layer deposition (PEALD or plasma ALD).

Briefly, a new process of bevel etching has been designed by the inventors along with a bevel etcher or bevel etcher assembly to carry out this new bevel etching process to etch or clean the edge (or bevel edge or bevel) of a substrate (which may also be labeled a “wafer” herein). The new bevel etcher assembly is particularly well-suited for use in plasma deposition systems or tools that may include multiple modules for performing plasma deposition and may also include chambers, modules, stages, or other spaces outside the process or reaction chambers (or “vacuum chambers”) used for plasma deposition. The bevel etcher assembly may be positioned within one of these non-deposition spaces, e.g., spaces where pressure may be at or near normal or atmospheric pressure. For example, the bevel etcher assembly may be provided in the equipment front end module (EFEM), and the bevel etcher assembly generally includes a substrate rotation mechanism or unit combined with an atmospheric plasma unit to provide a cross flow of atmospheric plasma (or atmospheric-pressure plasma) to the rotating substrate edge to provide a desired amount of etching (or cleaning) of the wafer edge or bevel.

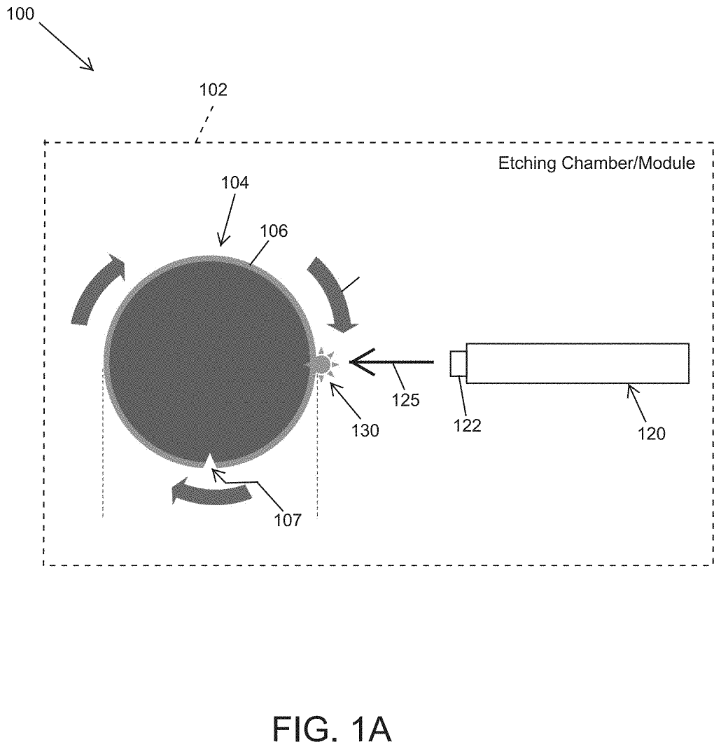

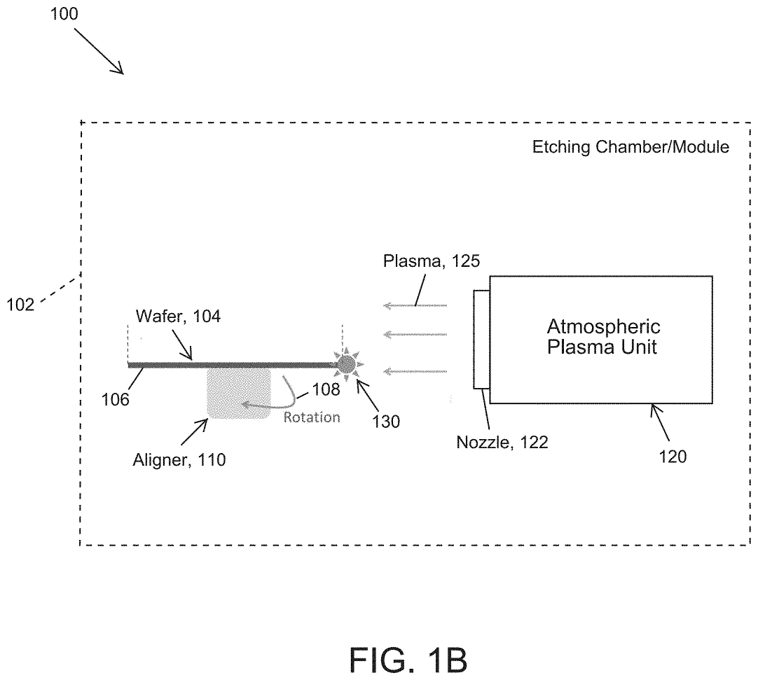

FIGS. 1A and 1B are top and side functional schematic views, respectively, of a chamber or module 102 in which a bevel etcher assembly 100 of the present description is positioned and operated to clean an edge or bevel 106 of a substrate 104. As shown, the assembly 100 incudes a rotation mechanism or unit 110 that is used to support a substrate 104. Further, the rotation mechanism 110 operates to rotate, as shown with arrows 108, the substrate 104 about its center axis. The chamber/module 102 typically is a space in which the pressure may be maintained at or near normal or atmospheric pressure, and, in some embodiments, the chamber/module 102 is a rotated wafer stage (e.g., a module used for cooling).

The rotation mechanism 110 may take a wide variety of forms to implement the etcher assembly 100. As shown, the substrate or wafer 104 has an outer edge or bevel 106 in which a notch 107 is provided. In such implementations, the rotation mechanism 110 may take the form of a notch aligner that operates to support the wafer 104, oriented to be horizontal or with its upper and lower surfaces in horizontal or nearly horizontal planes. The notch aligner further is operable to rotate the wafer 104 about its center axis at a rotation rate in a desired range such as a rotation speed in the range of 10 to 500 rotations per minute (RPM) and in one exemplary test case a speed in the range of 10 to 30 RPM. A number of aligners may be used for the rotation mechanism 110 such as, but not limited to, the design(s) shown in U.S. Pat. No. 6,454,516, which is incorporated herein in its entirety by reference.

The bevel etcher assembly 100 further includes an atmospheric plasma unit 120 that may be positioned in the chamber/module 102 adjacent to the rotation mechanism 110. The atmospheric plasma unit 120 includes a nozzle 122, and, during its operations, a flow, shown by arrows 125, of atmospheric plasma 125 is output form the nozzle 122 toward the wafer edge 106 to cause etching or cleaning as shown at 130 of materials from the edge or bevel 106. The nozzle 122 may be configured to produce the plasma flow 125 as a planar sheet, and, to this end, may be provided in the form of a linear slit or opening in the housing of the unit 120 with a height in the range of 5 to 100 millimeters or the like so as to provide a planar sheet of plasma flow 125 with similar dimensions as it contacts the edge 106 of the wafer 104. The nozzle 122 may be spaced apart from the edge 106 a desired distance such as a distance in the range of 0.5 to 100 mm or the like. In other cases, the nozzle 122 is configured differently such as to provide the plasma flow as a sharp head. In general, the plasma gun may have any of the following types of nozzles: (a) a gathering type of nozzle (e.g., a focusing cone or the like); (b) a diffusing type of nozzle (e.g., an expanding cone; and (c) a slit type of nozzle.

As shown, the plasma flow 125 is a cross flow to the wafer 104 meaning that it is in a direction that is coplanar with or parallel (plus or minus 1 to 5 degrees) to the plane of the wafer 104 (or its upper and lower surfaces). In some embodiments, though, the unit 120 (or its nozzle 122) may be tilted upward or downward to provide the plasma or plasma flow 125 to the edge 106 at an upward or downward angle such as at a tilt angle in the range of 1 to 30 degrees. Additionally, the plasma flow 125 is typically provided at vertical or in a vertical plane from 1 to 30 degrees from vertical. The rotation 108 of the wafer 104 is desirable to deliver the plasma 125 with a perpendicular orientation relative to a vertical plane containing the wafer edge 106 about the entire periphery or circumference of the wafer 104. The plasma 125 may be provided at a desired pressure at 0.9 atm to 1.1 atm and/or flow rate such as in the range of from 10 to 100 L/min.

The atmospheric plasma unit 120 may take a number of forms to implement the assembly 100. For example, the plasma unit 120 may include a plasma gun with a nozzle of any of the types listed above, and the plasma gun may be mounted on the floor, the ceiling, or the sidewall of the room with the nozzle outlet targeting or focused upon the outer edge of a rotatable or rotating wafer. As shown, operation of the assembly involves the wafer 104 being placed on a support element/surface of the rotation mechanism 110. Once the wafer 104 is placed on the mechanism/stage 110, the mechanism 110 operates to rotate 108 the wafer 104 concurrently with operation of the atmospheric plasma unit 120 so that the wafer 104 is rotating with exposure to atmospheric plasma 125. In some useful embodiments, the unit 120 is chosen with a chemistry (e.g., argon (Ar)/oxygen (O₂)) so that the plasma 125 is O₂ atmospheric plasma (e.g., plasma with an active oxygen species) while other embodiments may use Ar/O₂ atmospheric plasma or N₂/O₂ atmospheric plasma.

This plasma exposure can be useful in eliminating the undesirable material film, which has been generated on the edge 106 and/or backside of the wafer 104 in a previous deposition operation. The prior operation may be a plasma CVD or ALD deposition of a carbon film (e.g., amorphous carbon) or films of SiC, SiO, SiN, or other material. The plasma unit 120 can by chosen to supply the O₂ or other atmospheric plasma, such as Ar/O₂ atmospheric plasma or N₂/O₂ atmospheric plasma, through the nozzle 122 (which may take the form of elongated slit) and achieve desired etching at the wafer edge or bevel 106 with plasma 125 flowing perpendicular to a vertical plane containing the edge 106 about entire periphery of the wafer 104.

The bevel etching processes and assemblies are well suited for integration into many plasma deposition systems or apparatus designs because the bevel etching never requires a vacuum environment. Instead, the bevel etcher may be provided in an aligner module (chamber or stage), in the cooling stage, or other non-vacuum or atmospheric pressure space in the deposition system or apparatus. In this manner, the bevel etcher embedded in a plasma deposition system or platform can help to maintain substrate throughput and limit any undesirable increase in tool cost.

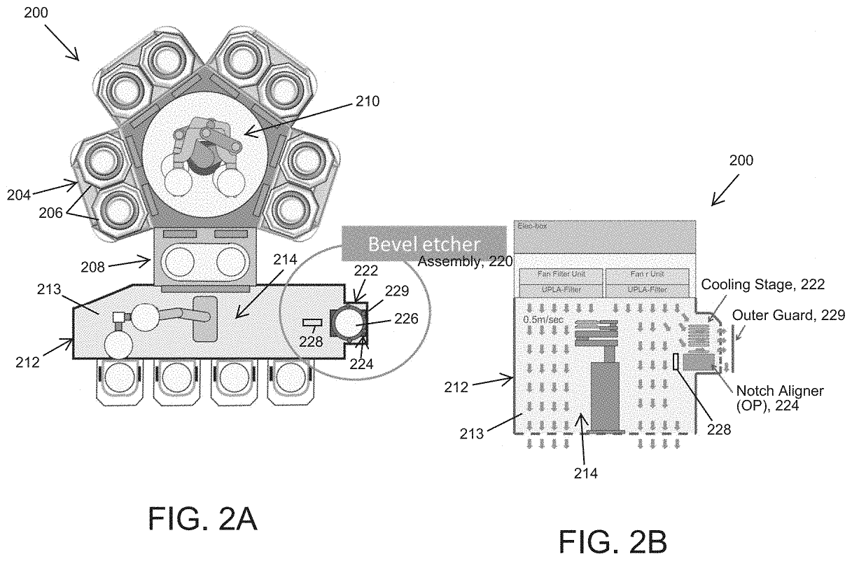

In this regard, FIGS. 2A and 2B illustrate a plasma deposition system 200 with top and side views, respectively, that includes an embodiment of a bevel etcher assembly 220 of the present description. As shown, the plasma deposition system (or platform) 200 includes a number of deposition modules 204 with reaction or vacuum chambers 206 for depositing, such as with PECVD or PEALD, a thin film of a material such as a carbon film (which may take the form of amorphous carbon) and/or a film or layer of SiC, SiO, SiN, or other material. A substrate handling or transfer mechanism (or robot) 210 is provided to move the wafers from transfer bay 208 into one or more of the chambers 206 of one or more of the module 204 to complete the plasma deposition.

The system 200 further includes an atmospheric or non-vacuum pressure space 213 enclosed by housing 212, and another substrate handling or transfer mechanism (or robot) 214 is provided in this space 213 to move wafers from the transfer bay 208 to desired locations within the space 213. Inside this space, the system 200 is shown to include a cooling stage (or chamber or module) 222, and a wafer 226 has been moved or positioned within the cooling stage 222. Cooling gases flow within the space 213 and cooling stage 222 to exit via or near the outer guard 229 (as well as other exhaust ports as shown).

The bevel etcher assembly 220 is shown to be positioned in the cooling stage or chamber 222, and the assembly 220 includes a notch aligner 224 upon which the wafer 226 is positioned. The aligner 224 acts as a rotation mechanism (as well as a notch-based wafer alignment device) and rotates the wafer 226 about its center axis. The bevel etcher assembly 220 further includes an atmospheric plasma unit 228 that operates, as discussed with reference to FIGS. 1A and 1B, to output an atmospheric plasma that is provide in cross flow to the rotating wafer 226 to etch or clean the edge or bevel of the wafer 226.

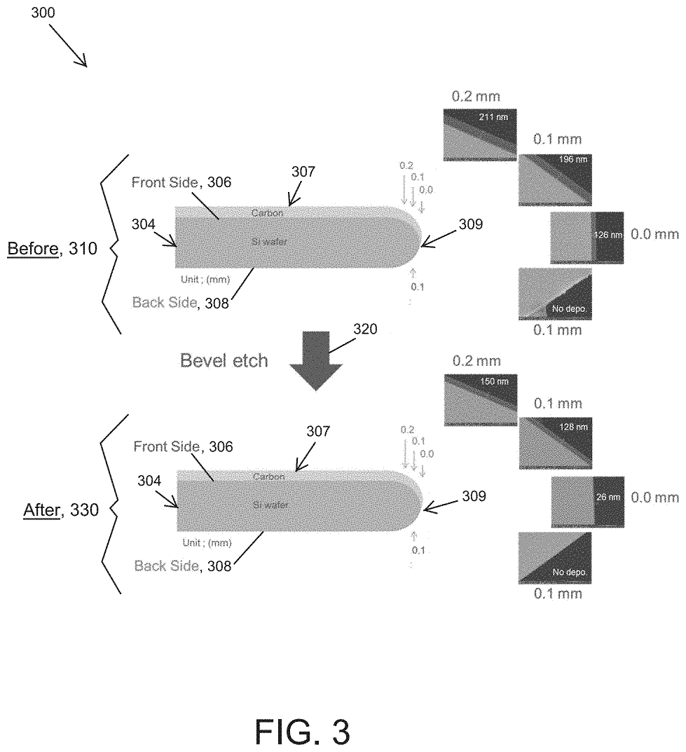

FIG. 3 illustrates bevel etching test results schematically at 300 that were achieved with the bevel etcher design of the present description (e.g., operations of the etcher 100 of FIG. 1). The etching was performed after plasma deposition of a carbon film 370 on a top or front side 306 of a wafer 304 having a back or bottom side 308, and no bevel mask was used. The precursor was Alpha-7, the radio frequency (RF) power was 75 W (deposition) and 360 W (TRT), and the pressure was 1100 Pa. At 310, the wafer 304 is shown after deposition but before etching of the bevel or edge 309. As shown in the scanning transmission electron microscopy (STEM) images, at 0.2 mm from outer most point of the edge 309 (or at maximum wafer radius) the carbon film 307 had a thickness of 211 nm, at 0.1 mm from the outer most point of the edge 309 the carbon film 307 had a thickness of 196 nm, at the outer most point of the edge 309 (or at the wafer outer radius) the carbon film 307 had a thickness of 126 nm, and on the back side 308 at 0.1 mm from outer most point of the edge 309 (as well as at smaller radial positions) there was no deposition of the carbon material.

Bevel etching as shown at 320 was performed with a bevel etcher of the present description using the following operating parameters: (a) a rotation and etching duration of 60 minutes; (b) a rotating speed or rate of 30 RPM; (c) plasma power at the atmospheric plasma unit of 50 W maximum; (d) a plasma chemistry of Ar/O₂; (e) a separation distance between the nozzle and the wafer edge of 3.0 mm; and (f) a pressure in the chamber/space where etching occurred of 1 atm.

At 330, the wafer 304 is shown after etching of the bevel or edge 309. As shown in the scanning transmission electron microscopy (STEM) images, at 0.2 mm from outer most point of the edge 309 (or at maximum wafer radius) the carbon film 307 had a thickness of 150 nm, at 0.1 mm from the outer most point of the edge 309 the carbon film 307 had a thickness of 128 nm, at the outer most point of the edge 309 (or at the wafer outer radius) the carbon film 307 had a thickness of 26 nm, and on the back side 308 at 0.1 mm from outer most point of the edge 309 (as well as at smaller radial positions) there was no deposition of the carbon material. The results clearly show effective film 307 (e.g., carbon) thickness reduction after the bevel etching 320.

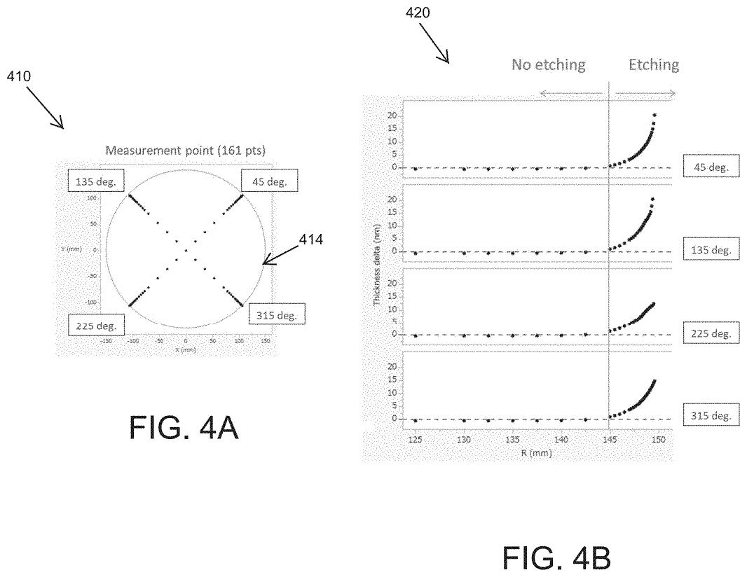

FIGS. 4A and 4B are graphs 410 and 420 illustrating measurement points on an etched or cleaned wafer and thickness profiles on the wafer edge, respectively, after bevel etching as discussed above with reference to FIGS. 3A and 3B in a test environment. Particularly, graphs 410 and 420 show ellipsometry measurement results before and after bevel etching in four directions (e.g., four direction scan at 45 degrees, 135 degrees, 225 degrees, and 315 degrees) for a wafer with a radius of 150 mm.

This data provides two important messages or advantages of the new bevel etcher. First, bevel etching has been confined to a wafer radius of 145 mm or greater (or in an edge area extending up to but not exceeding 5 mm from the outermost edge or periphery of the wafer). No etching was found at radii less than 145 mm. Second, bevel etching was achieved uniformly at each of the measured four directions such that one can conclude that the new bevel etcher can achieve a radially confined etching profile in all directions or about an entire periphery of the wafer (e.g., along the entire edge or bevel).

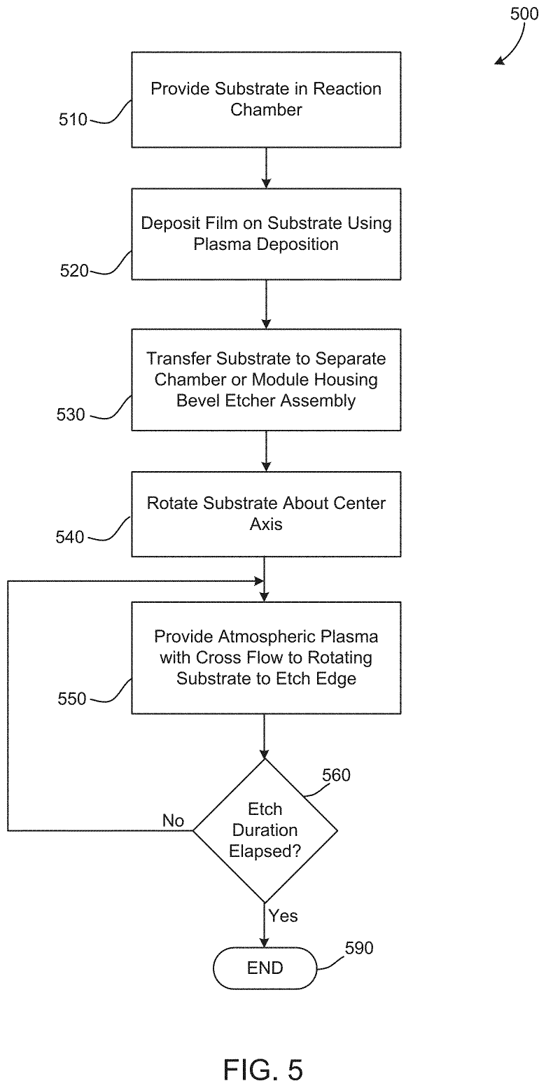

FIG. 5 is a process flow diagram for a deposition or fabrication process 500 that includes an edge etching according to the present description using atmospheric plasma. The method 500 includes the step of providing a substrate or wafer in a reaction chamber. This may involve operating a plasma deposition system or platform with a robot to move a substrate into a process or reaction chamber configured for PECVD, PEALD, or the like. At step 520, the method 500 continues with depositing a film on a top or upper surface of the substrate, which may involve no mask in some cases. Step 520 may involve providing a vacuum and performing plasma-enhance CVD or ALD to provide a carbon film (or layer of amorphous carbon) or a film or layer of SiC, SiO, SiN, or other material on the substrate.

The method 500 continues with transferring, such as with a robot or other substrate handling mechanism, the substrate from the process or reaction chamber to another, separate chamber or module in which a bevel etcher assembly is positioned or housed. Typically, this new chamber or module defines a space at atmospheric pressure (or not at vacuum in many cases). Step 530 may involve placing the substrate on a substrate support of a rotation mechanism such as a notch aligner. Then, at step 540, the substrate is rotated about its center axis at a rotation rate falling within a predefine rotation range (e.g., 20 to 500 RPM or the like).

While the substrate is rotated, the method 500 continues at 550 with providing atmospheric plasma with a crossflow to the rotating substrate to etch the edge of the substrate. Stated differently, steps 540 and 550 are performed at least partially concurrently and for a predefined rotation or etching duration (e.g., from 30 to 90 minutes with 60 minutes used in one exemplary implementation). At step 560, the method 500 involves checking to see if the etching duration or period has elapsed. If not, the method 500 continues at 550 (and 540). If yes, the method 500 may end at 590. Step 550 may be performed by operations of an atmospheric plasma unit, and a system may include a controller for controlling operations of the rotating mechanism to perform step 540 and for controlling operations of the atmospheric plasma unit to perform step 550 for the etching duration or period.

Benefits, other advantages, and solutions to problems have been described herein with regard to specific embodiments. However, the benefits, advantages, solutions to problems, and any elements that may cause any benefit, advantage, or solution to occur or become more pronounced are not to be construed as critical, required, or essential features or elements of the disclosure.

Furthermore, the described features, advantages, and characteristics of the disclosure may be combined in any suitable manner in one or more embodiments. One skilled in the relevant art will recognize that the subject matter of the present application may be practiced without one or more of the specific features or advantages of a particular embodiment. In other instances, additional features and advantages may be recognized in certain embodiments that may not be present in all embodiments of the disclosure. Further, in some instances, well-known structures, materials, or operations are not shown or described in detail to avoid obscuring aspects of the subject matter of the present disclosure. No claim element is intended to invoke 35 U.S.C. 112(f) unless the element is expressly recited using the phrase “means for.”

The scope of the disclosure is to be limited by nothing other than the appended claims, in which reference to an element in the singular is not intended to mean “one and only one” unless explicitly so stated, but rather “one or more.” It is to be understood that unless specifically stated otherwise, references to “a,” “an,” and/or “the” may include one or more than one and that reference to an item in the singular may also include the item in the plural. Further, the term “plurality” can be defined as “at least two.” As used herein, the phrase “at least one of”, when used with a list of items, means different combinations of one or more of the listed items may be used and only one of the items in the list may be needed. The item may be a particular object, thing, or category. Moreover, where a phrase similar to “at least one of A, B, and C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A, B, and C. In some cases, “at least one of item A, item B, and item C” may mean, for example, without limitation, two of item A, one of item B, and ten of item C; four of item B and seven of item C; or some other suitable combination.

All ranges and ratio limits disclosed herein may be combined. Unless otherwise indicated, the terms “first,” “second,” etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Although exemplary embodiments of the present disclosure are set forth herein, it should be appreciated that the disclosure is not so limited. For example, although reactor systems are described in connection with various specific configurations, the disclosure is not necessarily limited to these examples. Various modifications, variations, and enhancements of the system and method set forth herein may be made without departing from the spirit and scope of the present disclosure.

What is claimed is:

1. A method of etching a bevel edge of a substrate, comprising:
providing a substrate with a bevel edge after a thin film has been deposited on a top surface of the substrate;
rotating the substrate about a center axis; and
during the rotating, etching the bevel edge by directing a flow of atmospheric plasma onto the bevel edge.

2. The method of claim 1, wherein the flow is parallel to the top surface of the substrate.

3. The method of claim 1, wherein the flow is orthogonal to a plane containing a region of the bevel edge being etched by the atmospheric plasma.

4. The method of claim 1, wherein the atmospheric plasma comprises an O₂ atmospheric plasma.

5. The method of claim 1, wherein the rotating includes rotating the substrate at a rotation rate in the range of 10 to 500 RPM.

6. The method of claim 1, wherein the etching is performed without loss of thickness of the thin film on the top surface at a radius spaced apart from an outer radius of the substrate less 5 mm.

7. The method of claim 1, wherein the substrate comprise a silicon (Si) wafer and wherein the thin film comprises at least one of a carbon film, amorphous carbon, SiC, SiO, and SiN.

8. The method of claim 1, wherein the providing step includes positioning the substrate upon a rotation mechanism operable to perform the rotating step and wherein the rotation mechanism comprises a notch aligner, a wafer cooling stage, or a rotating stage.

9. The method according to claim 8, wherein the rotation mechanism is located in a space of a plasma deposition system that is maintained at atmospheric pressure during operations of the plasma deposition system.

10. A bevel etcher apparatus, comprising:
a chamber;
a rotation mechanism adapted for supporting and rotating a wafer about a center axis; and
an atmospheric plasma unit with a nozzle outputting an atmospheric plasma, wherein the nozzle is oriented in the chamber to provide a crossflow of the atmospheric plasma to an outer edge of the wafer during the rotating by the rotation mechanism.

11. The apparatus of claim 10, wherein the chamber is maintained at atmospheric pressure during operation of the rotation mechanism and the atmospheric plasma unit.

12. The apparatus according to claim 10, wherein the nozzle is configured to provide the atmospheric plasma as a planar sheet or a sharp head and wherein the crossflow is oriented such that the planar sheet is orthogonal to a plane containing a point of the outer edge of the wafer proximate to the atmospheric plasma unit.

13. The apparatus according claim 10, wherein the rotation mechanism is configured to support the wafer with a top surface in a horizontal plane and wherein the planar sheet of the atmospheric plasma is provided in a vertical plane.

14. The apparatus according claim 10, wherein the atmospheric plasma comprises O₂ atmospheric plasma, Ar/O₂ atmospheric plasma, or N₂/O₂ atmospheric plasma.

15. The apparatus according to claim 10, wherein the rotation mechanism comprises a notch aligner, a wafer cooling stage, or a rotating stage.

16. The apparatus according to claim 15, wherein the rotation mechanism is operable to rotate the wafer at a rotation rate in the range of 10 to 500 RPM.

17. A plasma deposition system for forming a thin film on a wafer, comprising:
a vacuum chamber adapted for plasma deposition of a thin film of material on a wafer;
a module, spaced apart from the vacuum chamber, with a space maintained at atmospheric pressure during operation of the plasma deposition system;
a substrate handling mechanism for transferring the wafer from the vacuum chamber to the space of the module;
a rotation mechanism in the space of the module for receiving and rotating the wafer; and an atmospheric plasma unit for generating a flow of atmospheric plasma, wherein the flow is directed onto a bevel edge of the wafer during operations of the rotation mechanism to rotate the wafer, whereby at least a portion of the thin film is etched from the bevel edge of the wafer.

18. The system of claim 17, wherein the flow is orthogonal to a plane containing a region of the bevel edge being etched by the atmospheric plasma.

19. The system according to claim 17, wherein the atmospheric plasma comprises an O₂ atmospheric plasma, Ar/O₂ atmospheric plasma, or N₂/O₂ atmospheric plasma.

20. The system according to claim 17, wherein the rotation mechanism comprises a notch aligner, a wafer cooling stage, or a rotating stage.

21. The system according to claim 20, wherein the rotation mechanism is operable to rotate the wafer at a rotation rate in the range of 10 to 500 RPM.

22. The system according to claim 17, wherein the plasma deposition comprises PECVD or PEALD and wherein the thin film comprises at least one of a carbon film, amorphous carbon, SiC, SiO, and SiN.
